(19) United States
(12) Patent Application Publication
(10) Pub. No.: US 2018/0277529 A1
(43) Pub. Date: Sep. 27, 2018

(54) SEMICONDUCTOR PACKAGE

(71) Applicant: Toshiba Memory Corporation, Tokyo (JP)

(72) Inventor: Manabu MATSUMOTO, Yokohama Kanagawa (JP)

(21) Appl. No.: 15/694,849

(22) Filed: Sep. 3, 2017

(30) Foreign Application Priority Data
Mar. 23, 2017 (JP) 2017-057714

(51) Int. Cl. H01L 25/18; H01L 25/065

(52) U.S. Cl. CPC H01L 25/18; H01L 25/0657; H01L 2225/06586; H01L 2225/0651; H01L 24/48; H01L 2225/06562; H01L 2225/06589; H01L 2924/1436; H01L 2924/14511; H01L 2225/06506

(57) ABSTRACT

A semiconductor package includes a substrate having opposing first and second surfaces, first memory chips stacked on the first surface, second memory chips stacked on the first surface, a controller chip for the first and second memory chips, installed on the first surface between the stacked first memory chips and the stacked second memory chips, a sealing portion that seals the first and second memory chips, and the controller chip, and a plurality of solder balls installed on the second surface. The first memory chips are stacked such that a first memory chip located directly above another first memory chip is shifted further toward the controller chip relative to said another first memory chip. The second memory chips are stacked such that a second memory chip located directly above another second memory chip is shifted further toward the controller chip relative to said another second memory chip.

### CROSS-REFERENCE TO RELATED APPLICATION

This application is based upon and claims the benefit of priority from Japanese Patent Application No. 2017-057714, filed Mar. 23, 2017, the entire contents of which are incorporated herein by reference.

### FIELD

Embodiments described herein relate to a semiconductor package.

### BACKGROUND

Semiconductor packages including semiconductor memory chips have been provided.

### DESCRIPTION OF THE DRAWINGS

FIG. 1 is a diagram illustrating an example of an electronic apparatus on which a semiconductor package according to an embodiment is mounted.

FIG. 2 is a diagram schematically illustrating a part of a configuration of a circuit board according to the embodiment.

FIG. 3 is a block diagram illustrating an example of a configuration of the semiconductor package according to the embodiment.

FIG. 4 is a sectional view illustrating the semiconductor package according to the embodiment.

FIG. 5 is a top view illustrating the semiconductor package according to the embodiment.

FIG. 6 is a diagram illustrating the semiconductor package excluding a part of the structure of FIG. 5 according to the embodiment.

FIG. 7 is a diagram illustrating an arrangement of solder balls according to the embodiment.

FIG. 8 is a diagram schematically illustrating assignment of the solder balls according to the embodiment.

### DETAILED DESCRIPTION

Embodiments of the present disclosure contribute to miniaturizing and thinning a semiconductor package. The embodiments of the present disclosure improve operation reliability of the semiconductor package.

In general, according to one embodiment, a semiconductor package includes a substrate having a first surface and a second surface opposite the first surface, a plurality of first memory chips stacked on the first surface, a plurality of second memory chips stacked on the first surface, a controller chip for the first and second memory chips, installed on the first surface between the stacked first memory chips and the stacked second memory chips, a sealing portion that seals the plurality of first memory chips, the plurality of second memory chips, and the controller chip, and a plurality of solder balls installed on the second surface. The first memory chips are stacked such that a first memory chip located directly above another first memory chip is shifted in a first direction further toward the controller chip relative to said another first memory chip. The second memory chips are stacked such that a second memory chip located directly above another second memory chip is shifted in a second direction further toward the controller chip relative to said another second memory chip.

Hereinafter, embodiments will be described with reference to the drawings.

In the present specification, some elements are given a plurality of expressions as examples. These expressions are merely examples and so other expressions may be given to these elements. Similarly, other expressions may be given to elements even where a plurality of expressions are not given to such elements.

The drawings are schematic and the relationship between thicknesses and planar dimensions, ratios of the thicknesses of layers, and the like may be different from actual ones. In addition, there may be cases in which the relationships and ratios of dimensions are different between drawings.

### First Embodiment

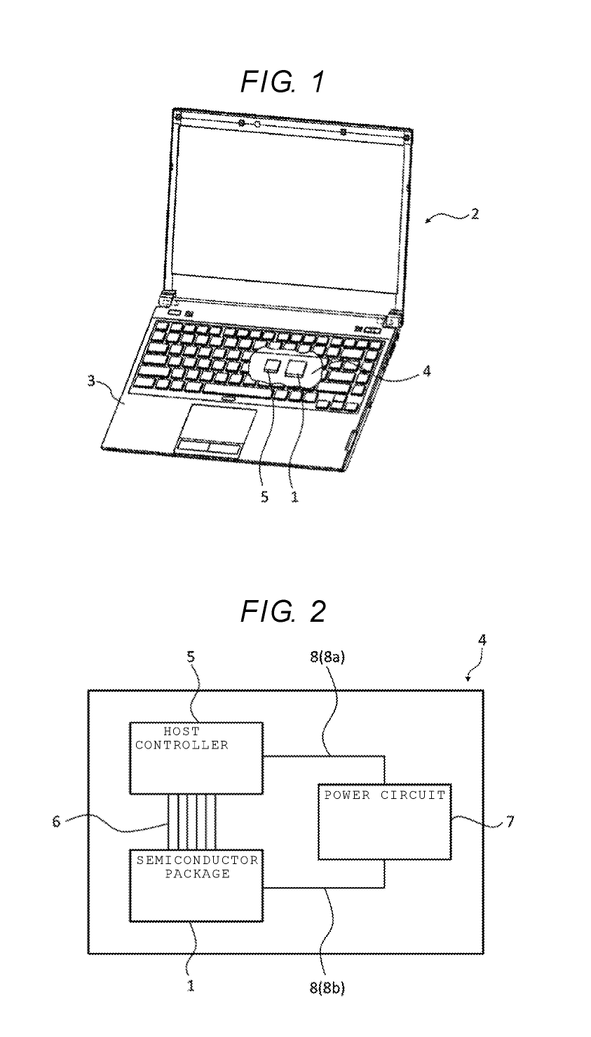

FIGS. 1 to 8 illustrate a semiconductor package 1 according to a first embodiment. The semiconductor package 1 is an example of a “semiconductor device.” The semiconductor package 1 according to the embodiment is a so-called ball grid array-solid state drive (BGA-SSD). A plurality of semiconductor memory chips and a controller are integrated to be configured as one BGA type package.

FIG. 1 is a diagram illustrating an example of an electronic apparatus 2 on which the semiconductor package 1 according to the embodiment is mounted. The electronic apparatus 2 includes a casing 3 and a circuit board 4 accommodated in the casing 3. The semiconductor package 1 is mounted on the circuit board 4 and functions as a storage device of the electronic apparatus 2. The circuit board 4 includes a host controller 5 (for example, a CPU). The host controller 5 includes, for example, a south bridge and controls an operation of the entire electronic apparatus 2 including the semiconductor package 1.

FIG. 2 is a diagram schematically illustrating a part of a configuration of the circuit board 4. The host controller 5 and the semiconductor package 1 according to the embodiment include interfaces conforming with a PCI-express (hereinafter, referred to as PCIe) standard. A plurality of signal lines are installed between the host controller 5 and the semiconductor package 1. The semiconductor package 1 exchanges high-speed signals conforming with the PCIe standard with the host controller 5 via the signal lines 6.

The host controller 5 and the semiconductor package 1 may not necessarily include the interface conforming with the PCIe standard. For example, another standard such as a Serial Attached SCSI (SAS), a Serial Advanced Technology Attachment (SATA), a Non volatile Memory Express (NVMe), or a Universal Serial Bus (USB) may be used.

A power circuit 7 is installed on the circuit board 4. The power circuit 7 is connected to the host controller 5 and the semiconductor package 1 via power lines 8 (8a and 8b). The power circuit 7 supplies power for operating the electronic apparatus 2 to the host controller 5 and the semiconductor package 1.

Next, the configuration of the semiconductor package 1 will be described.

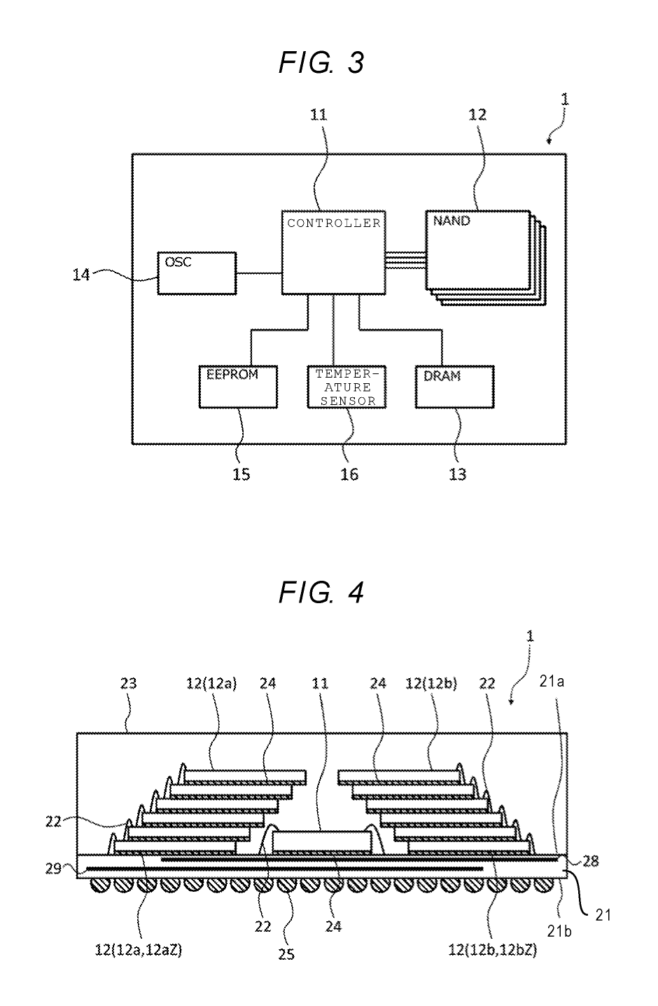

FIG. 3 is a block diagram illustrating an example of the configuration of the semiconductor package 1. The semiconductor package 1 includes a controller chip 11 (controller), semiconductor memory chips 12, a DRAM chip 13, an oscillator (OSC) 14, an electrically erasable and programmable ROM (EEPROM) 15, and a temperature sensor 16.

The controller chip 11 is a semiconductor chip that controls an operation of the semiconductor memory chips 12. The semiconductor memory chip 12 is, for example, an NAND chip (e.g., NAND flash memory). The NAND chip is a nonvolatile memory and retains data even in a state in which no power is supplied to the NAND chip. The DRAM chip 13 (DRAM) is used, for example, to preserve management information for managing the semiconductor memory chip 12 or cache data.

The oscillator (OSC) 14 supplies an operation signal having a predetermined frequency to the controller chip 11. The EEPROM 15 stores a control program or the like as fixed information. The EEPROM 15 is an example of a nonvolatile memory. The temperature sensor 16 detects a temperature inside the semiconductor package 1 and notifies the controller chip 11 of the detected temperature.

The controller chip 11 controls an operation of each unit of the semiconductor package 1 using temperature information received from the temperature sensor 16. For example, when the temperature detected by the temperature sensor 16 is equal to or higher than a predetermined temperature, the controller chip 11 adjusts an operation speed of the semiconductor package 1, or stops the operation of the semiconductor package 1 for a predetermined time or at a predetermined interval, and suppresses the temperature of the semiconductor package 1 to an allowable value or less.

Next, the structure of the semiconductor package 1 will be described.

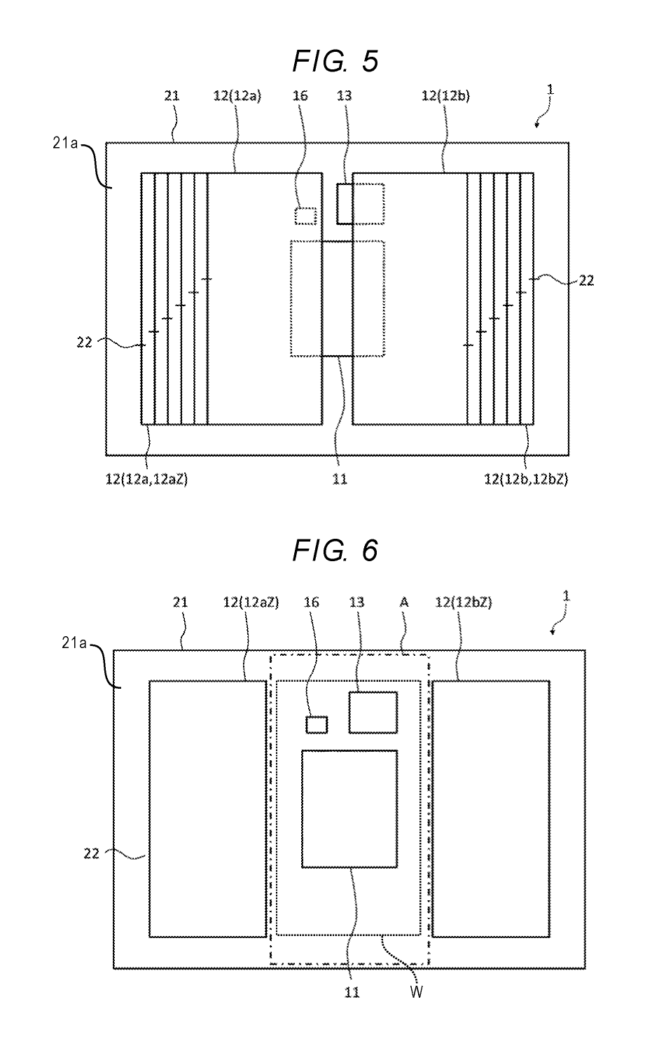

FIG. 4 is a sectional view illustrating the semiconductor package 1 according to the first embodiment. FIG. 5 is a top view illustrating the semiconductor package 1 according to the first embodiment. In FIGS. 4 and 5, to facilitate the description, configurations of parts of the oscillator 14, the EEPROM 15, and the like included in the semiconductor package 1 are not illustrated. In FIG. 5, a sealing portion 23 (which is made of molding material) to be described below is omitted in the configuration of the semiconductor package 1.

The semiconductor package 1 includes a substrate 21 (package substrate), the controller chip 11, the plurality of semiconductor memory chips 12, bonding wires 22, the sealing portion 23, mount films 24, and a plurality of solder balls 25.

The substrate 21 is, for example, a multi-layered wiring board and includes a power layer 28 and a ground layer 29. The substrate 21 includes a first surface 21a and a second surface 21b located opposite to the first surface 21a.

The controller chip 11 is mounted on the first surface 21a of the substrate 21. The controller chip 11 is fixed onto the first surface 21a of the substrate 21 by, for example, the mount film 24. The controller chip 11 is electrically connected to the substrate 21 by the bonding wire 22. The sealing portion 23 sealing the controller chip 11 and the bonding wires 22 is installed on the first surface 21a of the substrate 21.

The plurality of semiconductor memory chips 12 are mounted on the first surface 21a of the substrate 21 and are each stacked. The semiconductor memory chips 12 are fixed to the first surface 21a by the mount films 24. The stacked semiconductor memory chips 12 are mutually fixed by the mount films 24. The plurality of semiconductor memory chips 12 are electrically connected to the substrate 21 via the bonding wires 22. As a result, the semiconductor memory chips 12 are electrically connected to the controller chip 11 via the bonding wires 22 and the substrate 21.

As illustrated in FIGS. 4 and 5, in the embodiment, the plurality of semiconductor memory chips 12 are divided to two spots to be stacked on the first surface 21a of the substrate 21. Hereinafter, to facilitate the description, the semiconductor memory chips 12 belonging to one semiconductor memory chip group are particularly referred to as semiconductor memory chips 12a and the semiconductor memory chips 12 belonging to the other semiconductor memory chip group are particularly referred to as semiconductor memory chips 12b. Further, of the plurality of semiconductor memory chips 12, the semiconductor memory chips 12a and 12b located in the lowermost stacked layer are referred to as semiconductor memory chips 12aZ and 12bZ.

The DRAM chip 13 is mounted on the first surface 21a of the substrate 21. The DRAM chip 13 is fixed onto the first surface 21a by the mount film 24 (not illustrated). The DRAM chip 13 is electrically connected to the substrate 21 via the bonding wire 22. The DRAM chip 13 is electrically connected to the controller chip 11 via the substrate 21 and is used, for example, to preserve management information of the semiconductor memory chips 12 or cache data.

The temperature sensor 16 is mounted on the first surface 21a of the substrate 21, detects a temperature inside the semiconductor package 1, and notifies the controller chip 11 of the temperature. The temperature sensor 16 is located, for example, near the controller chip 11 inside the semiconductor package 1. More specifically, among the semiconductor memory chips 12aZ and 12bZ, the controller chip 11, and the DRAM chip 13 mounted on the first surface 21a of the substrate 21, a distance between the controller chip 11 and the temperature sensor 16 is the shortest.

As illustrated in FIGS. 4 and 5, on the first surface 21a of the substrate 21, the controller chip 11 is located in a region W (shown in FIG. 6) between the regions on which the lowermost semiconductor memory chips 12aZ and 12bZ are mounted among the plurality of stacked semiconductor memory chips 12a and 12b.

FIG. 6 is a diagram illustrating only the lowermost semiconductor memory chips 12aZ and 12bZ. In the embodiment, the controller chip 11, the DRAM chip 13, and the temperature sensor 16 are mounted in a region A between the semiconductor memory chips 12a and the semiconductor memory chips 12b. The region A in FIG. 6 is assumed to be a region surrounded by a one-dot chain line.

In the embodiment, as shown in FIG. 4, the semiconductor memory chips 12a and 12b are each stacked in an offset manner toward the center of the substrate 21. At this time, for example, when an arrangement direction of the semiconductor memory chip 12aZ, the controller chip 11, and the semiconductor memory chip 12bZ is a first direction, the plurality of semiconductor memory chips 12a are stacked to be shifted toward the controller chip 11 in the first direction. In other words, the plurality of semiconductor memory chips 12b are stacked to be shifted toward to the controller chip 11 in the first direction.

In the embodiment, the plurality of semiconductor memory chips 12 are divided into two groups on the first surface 21a of the substrate 21 to be stacked. Accordingly, for example, compared to when all the semiconductor memory chips 12 included in the semiconductor package 1 are stacked above one location, the height of the stacked semiconductor memory chips is lower, and thus, the thickness of the semiconductor package 1 can be less.

When the plurality of semiconductor memory chips 12 are stacked in two different locations on the substrate 21, the thickness of each semiconductor memory chip 12 can be set to be thicker than when all of the semiconductor memory chips 12 included in the semiconductor package 1 are stacked in one spot. If the thickness of each semiconductor memory chip 12 can be set to be thicker as described above, it is possible to improve mounting reliability or operation reliability and manufacturability of the semiconductor package 1.

In the embodiment, the plurality of semiconductor memory chips 12a and 12b are stacked to be shifted toward each other. The controller chip 11 is installed between the plurality of semiconductor memory chips 12a and the plurality of semiconductor memory chips 12b. By installing the controller chip 11 between the plurality of semiconductor memory chips 12a and the plurality of semiconductor memory chips 12b, it is possible to shorten wiring distances between the semiconductor memory chips 12 and the controller chip 11 in internal wiring layers of the substrate 21 or on the substrate 21.

As described above, by shortening the wiring distances between the semiconductor memory chips 12 and the controller chip 11, it is possible to suppress an increase in parasitic capacitance, parasitic resistance, parasitic inductance, or the like or signal delay. Further, it is easier to retain characteristic impedance of a signal wiring compared to when the wiring distances between the semiconductor memory chips 12 and the controller chip 11 are long.

Next, the plurality of solder balls 25 installed on the second surface 21b of the substrate 21 will be described.

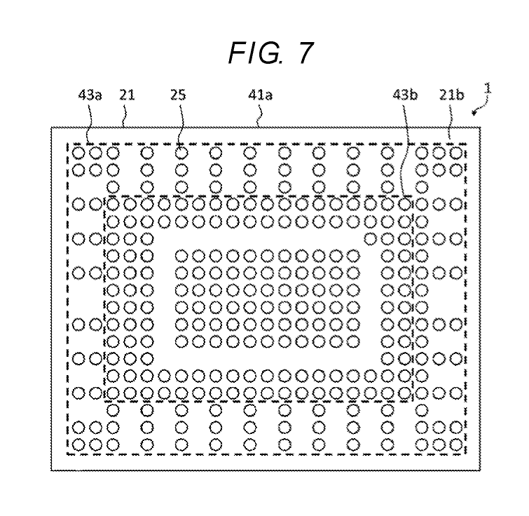

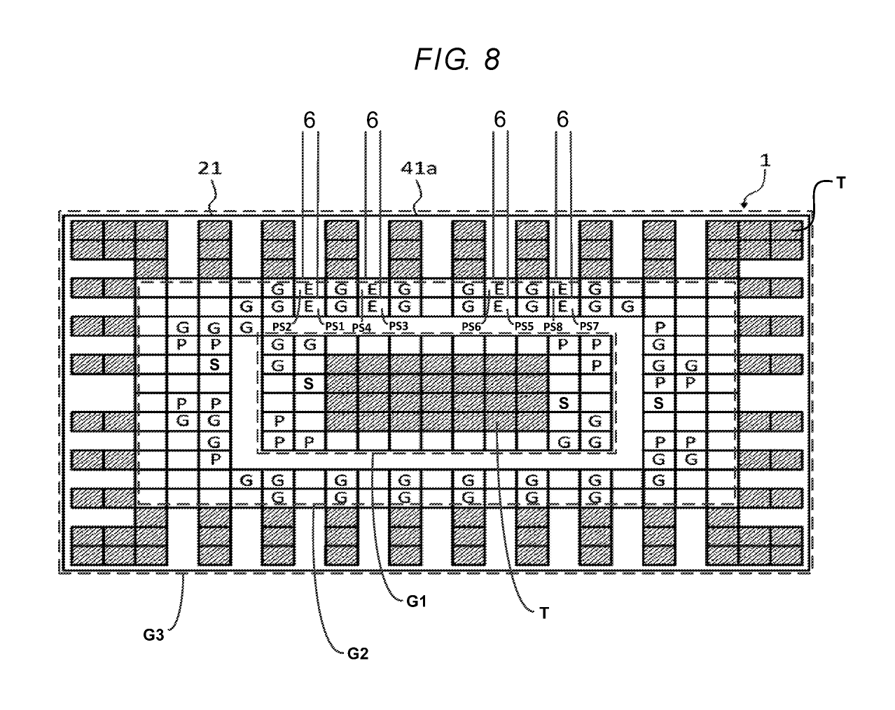

As illustrated in FIG. 4, the plurality of solder balls 25 for external connection are installed on the second surface 21b of the substrate 21. FIG. 7 illustrates the arrangement of the solder balls 25 on the second surface 21b of the substrate 21. As illustrated in FIG. 7, the plurality of solder balls 25 are not disposed on the entire second surface 21b of the substrate 21, but are disposed partially, for example. FIG. 8 schematically illustrates assignment of the solder balls 25. To facilitate the description, FIGS. 7 and 8 illustrate the solder ball arrangement on the circuit board 4 set as a reference (based on the orientation of the semiconductor package 1 when viewed from above).

A positional relationship, the number, assignment, and the like of the solder balls 25 illustrated in FIGS. 7 and 8 are merely examples. In addition, disposition of the chips such as the semiconductor memory chips 12 or the controller chips 11 and electronic components inside the semiconductor package 1 or external dimensions of the semiconductor package 1 can be appropriately changed.

The plurality of solder balls 25 according to the embodiment include PCIe signal balls E, other signal balls S, power balls P, ground balls G, and thermal balls T (which are heat dissipation balls). In FIG. 8, the thermal balls T are indicated by hatching. Additionally, the PCIe signal balls E, the power balls P, and the ground balls G are indicated by E, P, and G, respectively. In the assignment of FIG. 8, specific unassigned solder balls 25 may be assigned as any of the thermal balls T, the PCIe signal balls E, the power balls P, the ground balls G, and the other signal balls S.

As illustrated in FIG. 8, the plurality of solder balls 25 are divided to a first group G1, a second group G2, and a third group G3 to be disposed. The first group G1 is located in a middle portion of the substrate 21. In other words, a region in which the solder balls 25 of the first group 1G are located includes the center of the substrate 21. The first group G1 includes the plurality of thermal balls T installed in the middle portion of the substrate 21 and the plurality of power balls P, ground balls G, and signal balls S disposed to surround the plurality of thermal balls T.

The thermal balls T are electrically connected to the ground layer 29 or the power layer 28 of the substrate 21 shown in FIG. 4. Therefore, heat of the controller chip 11 or the like easily transfers to the thermal balls T via the ground layer 29 or the power layer 28.

The thermal balls T are not electrically connected to, for example, the controller chip 11 and the semiconductor memory chip 12. The thermal balls T are also not electrically connected to, for example, the DRAM chip 13 in addition to the controller chip 11 and the semiconductor memory chip 12.

The thermal balls T release part of the heat of the semiconductor package 1 to the circuit board 4 (i.e., dissipates the heat). For example, in the embodiment, since the semiconductor memory chips 12 are stacked on two different locations of the substrate 21, the controller chip 11 is mounted on a central portion of the substrate 21. The controller chip 11 is located in the middle portion of the substrate 21 to overlap the thermal balls T of the first group G1.

Here, in the controller chip 11, a heat amount at the time of an operation is larger than in other components (for example, the semiconductor memory chips 12 or the DRAM chip 13) included in the semiconductor package 1. In other words, during the operation of the semiconductor package 1, the temperature of the controller chip 11 can increase more than the temperature of the semiconductor memory chips 12 or the DRAM chip 13.

Accordingly, by installing the thermal balls T of the first group G1 at positions corresponding to the controller chip 11 on the substrate 21, it is possible to release part of the heat transferred from the controller chip 11 to the substrate 21 more efficiently to the circuit board 4 compared to a case where the thermal balls T of the first group G1 are installed at positions not corresponding to the controller chip 11 on the substrate 21. Here, in other words, “the positions corresponding to the controller chip 11” are the “position overlapping the controller chip 11.” That is, for example, when viewed from the side of the first surface 21a of the substrate 21, the thermal balls T of the first group G1 are installed in the region overlapping the controller chip 11 on the second surface 21b of the substrate 21.

In the embodiment, all of the plurality of solder balls 25 installed at the positions corresponding to the controller chip 11 may not necessarily be the thermal balls T. For example, half or more of the plurality of solder balls 25 installed at the positions corresponding to the controller chip 11 may be the thermal balls T.

The power balls P are electrically connected to the power layer 28 of the substrate 21 shown in FIG. 4 and supplies power to the semiconductor package 1. The ground balls G are electrically connected to the ground layer 29 of the substrate 21 shown in FIG. 4 to have a ground potential.

As illustrated in FIG. 8, the second group G2 is arranged in a frame shape surrounding the first group G1. There is a gap between the second group G2 and the first group G1. In other words, the solder balls 25 of the second group G2 and the solder balls 25 of the first group G1 are located to be separated more than the distance between the two adjacent solder balls 25 of the first group G1. The second group G2 has the PCIe signal balls E, the signal balls S, the power balls P, and the ground balls G.

The PCIe signal balls E form output differential pairs of high-speed differential signals. The PCIe signal balls E form input differential pairs of high-speed differential signals. Further, a solder ball set BS corresponding to a signal set formed from a pair of high-speed differential input signal and high-speed differential output signal is formed by the above-described input differential pair and output differential pair.

The semiconductor package 1 includes a plurality of the solder ball sets described above. In the embodiment, the semiconductor package 1 includes two solder ball sets, as illustrated in FIG. 8. The first solder ball set includes PCIe signal ball E that carries a PS1 signal (output, positive), PCIe signal ball E that carries a PS2 signal (output, negative), PCIe signal ball E that carries a PS3 signal (input, positive), PCIe signal ball E that carries a PS4 signal (input, negative). The second solder ball set includes PCIe signal ball E that carries a PS5 signal (output, positive), PCIe signal ball E that carries a PS6 signal (output, negative), PCIe signal ball E that carries a PS7 signal (input, positive), PCIe signal ball E that carries a PS8 signal (input, negative). The semiconductor package 1 may include one solder ball set or four or eight solder ball sets.

In the embodiment, the above-described solder ball sets are collectively disposed near a first side 41a of the substrate 21. In other words, the solder ball sets are located between the first side 41a of the substrate 21 and the center of the substrate 21. Therefore, when the semiconductor package 1 is mounted on the circuit board 4, the solder ball sets on the substrate 21 can be mounted to be located near the host controller 5.

As described above, by disposing the solder ball sets near the host controller 5, it is possible to shorten the wiring distances between the host controller 5 and the PCIe signal balls E.

The circuit board 4 includes the signal lines 6 electrically connecting the PCIe signal balls E to the host controller 5. The signal lines 6 are installed on, for example, the surface layer of the circuit board 4.

The signal lines 6 extend in, for example, a straight shape from a pad (not illustrated) connected to the PCIe signal balls E toward the host controller 5. The signal lines 6 have, for example, the same wiring length. That is, an isometric property of the signal lines 6 is ensured between the host controller 5 and the plurality of PCIe signal balls E.

As illustrated in FIG. 8, the second group G2 of the solder balls 25 include the plurality of ground balls G disposed around the PCIe signal balls E, some of which. Some of these ground balls G are installed between the PCIe signal balls E.

Therefore, the above-described differential input signals and differential output signals are electrically shielded to be independent from each other, and thus an influence of mutual interference of signals or external noise is prevented.

As illustrated in FIG. 8, the third group G3 of the solder balls 25 include the plurality of thermal balls T. The third group G3 is located on the outside of the second group G2. The third group G3 is located between the second group G2 and the outer circumference of the substrate 21. That is, the plurality of thermal balls T are located to be closer the outer circumference of the substrate 21 than the above-described solder ball sets.

In a region between the first side 41a of the substrate 21 and the solder ball set, the thermal balls T are disposed except for a region lined up with the solder ball set in a direction substantially perpendicular to the first side 41a of the substrate 21. That is, the thermal balls T are disposed except for a region through which the signal lines 6 pass. Thus, the signal lines 6 can extend in the straight shape on the surface layer of the circuit board 4 without physically interfering in the thermal balls T.

From another point of view, the thermal balls T are disposed in a region lined up with the ground balls G located between the PCIe signal balls E in the direction substantially perpendicular to the first side 41a of the substrate 21. The thermal balls T are located between the plurality of signal lines 6 and on both sides of the signal lines 6. The thermal balls T are electrically connected to, for example, the ground layer 29 of the substrate 21 and contribute to preventing the influence of mutual interference of signals flowing in the signal lines 6 or external noise as an electrical shield.

As illustrated in FIG. 7, the substrate 21 includes a first region 43a and a second region 43b. The second region 43b is a region located inside the second group G2 of the solder balls 25. The second region 43b is a region closer to the middle portion of the substrate 21 than the solder ball set.

On the other hand, the first region 43a is a region located outside the second group G2 of the solder balls 25. The first region 43a is a region located to be closer to the outer circumference of the substrate 21 than the solder ball set. An arrangement density of the thermal balls T in the second region 43b is higher than a disposition density of the thermal balls T in the first region 43a. The “disposition density” is a value obtained by dividing the number of thermal balls T disposed in each region by the area of each region.

Next, the disposition of the power balls P and the ground balls G will be described.

As illustrated in FIG. 8, the plurality of power balls P and the plurality of ground balls G are disposed to be substantially point-symmetric with respect to the center of the substrate 21. The “substantially point-symmetric” includes a case in which, for example, a small number (for example, one) of ground balls G are not disposed to be point-symmetric in addition to a case in which the balls are completely point-symmetric.

From another point of view, one of the plurality of power balls P and the plurality of ground balls G may be disposed to be point-symmetric with respect to the center of the substrate 21. In the embodiment, the plurality of power balls P are disposed to be point-symmetric with respect to the center of the substrate 21.

Here, when the plurality of power balls P and the plurality of ground balls G are not disposed to be substantially point-symmetric and the semiconductor package 1 is mounted on the substrate 21 by erroneously rotating 180 degrees in a regular direction, there is a possibility of a power pad (not illustrated) of the circuit board 4 is connected to the ground balls G of the semiconductor package 1 to be short-circuited.

On the other hand, when the plurality of power balls P and the plurality of ground balls G are disposed to be substantially point-symmetric with respect to the center of the substrate 21 as in the embodiment, and even when the semiconductor package 1 is mounted on the substrate 21 by erroneously rotating 180 degrees in the regular direction, a correspondence relation between the plurality of power balls P and a plurality of power pads, and the plurality of ground balls G and a plurality of ground pads (not illustrated) is maintained. Therefore, there is no possibility of the occurrence of short-circuiting and it is possible to prevent the entire system and the semiconductor package 1 from being damaged because of the short-circuiting.

The pads of the circuit board 4 include the power pads to which the power balls P are connected and the ground pads to which the ground balls G are connected.

Even when the semiconductor package 1 is mounted on the circuit board 4 by erroneously rotating 180 degrees in the regular direction, by disposing the plurality of power balls P and the plurality of ground balls G to be substantially point-symmetric, the correspondence relation between the power balls P and the power pads, and the ground balls G and the ground pads is maintained.

Further, by installing the controller chip 11 between the plurality of semiconductor memory chips 12a and the plurality of semiconductor memory chips 12b, wirings connecting the controller chip 11 to the plurality of semiconductor memory chips 12a and the plurality of semiconductor memory chips 12b extend from both sides of the controller chip 11. Therefore, it is possible to prevent complication of the wirings on the substrate 21 (or inside the substrate 21).

In the embodiment, the temperature sensor 16 is mounted on the first surface 21a of the substrate 21, and is installed in the region formed between the plurality of semiconductor memory chips 12a and the plurality of semiconductor memory chips 12b. As a result, the temperature sensor 16 is installed near the controller chip 11, and thus the accuracy of the temperature detection of the semiconductor package 1 can be improved.

The controller chip 11 is installed in the region between the plurality of semiconductor memory chips 12a and the plurality of semiconductor memory chips 12b. That is, in the embodiment, the controller chip 11 is installed in the region including the center of the substrate 21. Therefore, on the second surface 21b of the substrate 21, the thermal balls T are installed at the positions corresponding to the region in which the controller chip 11 is mounted, and thus heat dissipation characteristics of the semiconductor package 1 are improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor package comprising:
a substrate having a first surface and a second surface opposite the first surface;
a plurality of first memory chips stacked on the first surface;
a plurality of second memory chips stacked on the first surface;
a controller chip for the first and second memory chips, installed on the first surface between the stacked first memory chips and the stacked second memory chips;
a sealing portion that seals the plurality of first memory chips, the plurality of second memory chips, and the controller chip; and
a plurality of solder balls installed on the second surface,
wherein the first memory chips are stacked such that a first memory chip located directly above another first memory chip is shifted in a first direction further toward the controller chip relative to said another first memory chip, and
wherein the second memory chips are stacked such that a second memory chip located directly above another second memory chip is shifted in a second direction further toward the controller chip relative to said another second memory chip.

2. The semiconductor package according to claim 1, wherein
the first and second directions are opposite directions.

3. The semiconductor package according to claim 1,
wherein the plurality of solder balls include a plurality of first solder balls electrically connected to at least one of the first memory chips, the second memory chips, and the controller chip, and a plurality of second solder balls electrically disconnected from each of the first memory chips, the second memory chips, and the controller chip.

4. The semiconductor package according to claim 3,
wherein in a region of the second surface of the substrate overlapping the controller chip, the number of installed second solder balls is more than the number of installed first solder balls.

5. The semiconductor package according to claim 4,
wherein the substrate includes a ground layer and a power layer and the plurality of second solder balls are electrically connected to the ground layer.

6. The semiconductor package according to claim 1, further comprising:
a temperature sensor is mounted on the first surface of the substrate nearer to the controller chip than the first or second memory chips.

7. The semiconductor package according to claim 1,
wherein the substrate includes a first region on the second surface and a second region on the second surface, which is inside the first region, the first region having a lower density of installed solder balls than the second region.

8. The semiconductor package according to claim 7,
wherein only the second solder balls are installed in the first region.

9. A semiconductor package comprising:
a substrate having a first surface and a second surface opposite the first surface;
a plurality of first memory chips stacked on the first surface and offset toward a center of the substrate;
a plurality of second memory chips stacked on the first surface and offset toward the center of the substrate;
a controller chip for the first and second memory chips installed on the first surface between the first memory chips and the second memory chips;
a sealing portion that seals the first memory chips, the second memory chips, and the controller chip; and
a plurality of solder balls installed on the second surface.

10. The semiconductor package according to claim 9, wherein
the first memory chips are offset toward the center of the substrate in a first direction, and the second memory chips are offset toward the center of the substrate in a second direction that is opposite to the first direction.

11. The semiconductor package according to claim 9,
wherein the plurality of solder balls include a plurality of first solder balls electrically connected to at least one of the first memory chips, the second memory chips, and the controller chip, and a plurality of second solder balls electrically disconnected from each of the first memory chips, the second memory chips, and the controller chip.

12. The semiconductor package according to claim 11,
wherein in a region of the second surface of the substrate overlapping the controller chip, the number of installed second solder balls is more than the number of installed first solder balls.

13. The semiconductor package according to claim 12,
wherein the substrate includes a ground layer and a power layer and the plurality of second solder balls are electrically connected to the ground layer.

14. The semiconductor package according to claim 9, further comprising:
a temperature sensor is mounted on the first surface of the substrate nearer to the controller chip than the first or second memory chips.

15. The semiconductor package according to claim 9,
wherein the substrate includes a first region on the second surface and a second region on the second surface, which is inside the first region, the first region having a lower density of installed solder balls than the second region.

16. The semiconductor package according to claim 15, wherein only the second solder balls are installed in the first region.

17. A semiconductor package comprising:
a substrate having a first surface and a second surface opposite the first surface;
a plurality of first memory chips stacked on the first surface;
a plurality of second memory chips stacked on the first surface;
a controller chip for the first and second memory chips, installed on the first surface between the stacked first memory chips and the stacked second memory chips;
a sealing portion that seals the plurality of first memory chips, the plurality of second memory chips, and the controller chip; and
a plurality of solder balls installed on the second surface,
wherein an uppermost first memory chip and an uppermost second memory chip partially overlap the controller chip when viewed along a direction perpendicular to the first surface.

18. The semiconductor package according to claim 17,
wherein the plurality of solder balls include a plurality of first solder balls electrically connected to at least one of the first memory chips, the second memory chips, and the controller chip, and a plurality of second solder balls electrically disconnected from each of the first memory chips, the second memory chips, and the controller chip.

19. The semiconductor package according to claim 18,
wherein in a region of the second surface of the substrate overlapping the controller chip, the number of installed second solder balls is more than the number of installed first solder balls.

20. The semiconductor package according to claim 19,
wherein the substrate includes a ground layer and a power layer and the plurality of second solder balls are electrically connected to the ground layer.
